(19) United States
(12) Patent Application Publication
(10) Pub. No.: US 2026/0123039 A1
(43) Pub. Date: Apr. 30, 2026

(54) SEMICONDUCTOR STRUCTURE AND FABRICATION METHOD THEREOF

(71) Applicant: UNITED MICROELECTRONICS CORP., Hsin-Chu City (TW)

(72) Inventors: Ping-Chen Tsai, Tainan City (TW); Min-Hua Tsai, Tainan City (TW); Chih-Wei Chang, Tainan City (TW); Bin-Siang Tsai, Changhua County (TW)

(73) Assignee: UNITED MICROELECTRONICS CORP., Hsin-Chu City (TW)

(21) Appl. No.: 18/955,987

(22) Filed: Nov. 22, 2024

(30) Foreign Application Priority Data
Oct. 25, 2024 (TW) 113140772

(51) Int. Cl. H01L 27/088; H01L 21/02; H01L 21/762; H01L 29/66; H01L 29/78

(52) U.S. Cl. CPC H10D 84/834; H10D 30/024; H10D 30/62; H10P 14/3454; H10P 14/69215; H10W 10/014; H10W 10/17

(57) ABSTRACT

A semiconductor structure includes a substrate having a low-voltage device region and a high-voltage device region thereon; a plurality of finFETs disposed in the low-voltage device region; at least one high-voltage transistor disposed in the high-voltage device region; and a trench isolation structure disposed in the substrate between the low-voltage device region and the high-voltage device region. The trench isolation structure includes a trench-fill layer and a protective condition layer between the trench-fill layer and the substrate. The protective condition layer includes an amorphous silicon layer.

### BACKGROUND OF THE INVENTION

### 1. Field of the Invention

The present invention relates to the field of semiconductor technology, and more particularly to an improved embedded high-voltage semiconductor structure and a method for manufacturing the same.

### 2. Description of the Prior Art

Driven by Moore's Law, the 14 nm FinFET process continues to pursue higher device density and lower power consumption. However, with the increasing complexity of integrated circuits, the demand for high-voltage devices is also growing. Embedding high-voltage devices into the advanced 14 nm FinFET process not only enables system-level integration but also improves system performance and reliability.

For the development of embedded high-voltage (eHV) FinFET devices, current solutions isolate the planar high-voltage/medium-voltage regions using undoped silicate glass (USG) that has undergone a steam anneal. However, this approach results in severe through-fin loading, which leads to the reduction of isolated fin critical dimension (Iso-Fin CD shrinkage), and device shifting due to stress-induced cracking.

### SUMMARY OF THE INVENTION

One objective of this invention is to provide an improved embedded high-voltage semiconductor structure and its fabrication method to address the shortcomings or deficiencies of existing technologies.

One aspect of the invention provides a semiconductor structure including a substrate having a low-voltage device region and a high-voltage device region thereon; a plurality of finFETs disposed in the low-voltage device region; at least one high-voltage transistor disposed in the high-voltage device region; and a trench isolation structure disposed in the substrate between the low-voltage device region and the high-voltage device region, wherein the trench isolation structure comprises a trench-fill layer and a protective condition layer between the trench-fill layer and the substrate, and wherein the protective condition layer comprises an amorphous silicon layer.

According to some embodiments, the trench-fill layer comprises a high-density plasma (HDP) silicon oxide layer.

According to some embodiments, the amorphous silicon layer has a thickness of 50-100 angstroms.

According to some embodiments, the protective condition layer further comprises a SiₓO_{y} layer disposed between the amorphous silicon layer and the trench-fill layer, where x:y is between 1:1 and 1:2.

According to some embodiments, the SiₓO_{y} layer exhibits a graded silicon content, with a higher silicon concentration near the amorphous silicon layer and a lower silicon concentration near the trench-fill layer.

According to some embodiments, the SiₓO_{y} layer has a thickness of 100-200 angstroms.

According to some embodiments, the protective condition layer further comprises a nitride buffer layer between the amorphous silicon layer and the substrate.

According to some embodiments, the nitride buffer layer comprises a silicon oxy-nitride layer or a silicon nitride layer.

According to some embodiments, the protective condition layer further comprises an oxide buffer layer between the amorphous silicon layer and the substrate.

According to some embodiments, the oxide buffer layer comprises an in-situ steam growth (ISSG) oxide layer.

Another aspect of the invention provides a method for forming a semiconductor structure. A substrate having a low-voltage device region and a high-voltage device region thereon is provided. A plurality of finFETs are formed in the low-voltage device region. At least one high-voltage transistor is formed in the high-voltage device region. A trench isolation structure is formed in the substrate between the low-voltage device region and the high-voltage device region. The trench isolation structure comprises a trench-fill layer and a protective condition layer between the trench-fill layer and the substrate. The protective condition layer comprises an amorphous silicon layer.

According to some embodiments, the trench-fill layer comprises a high-density plasma (HDP) silicon oxide layer.

According to some embodiments, the amorphous silicon layer has a thickness of 50-100 angstroms.

According to some embodiments, the protective condition layer further comprises a SiₓO_{y} layer disposed between the amorphous silicon layer and the trench-fill layer, where x:y is between 1:1 and 1:2.

According to some embodiments, the SiₓO_{y} layer exhibits a graded silicon content, with a higher silicon concentration near the amorphous silicon layer and a lower silicon concentration near the trench-fill layer.

According to some embodiments, the SiₓO_{y} layer has a thickness of 100-200 angstroms.

According to some embodiments, the protective condition layer further comprises a nitride buffer layer between the amorphous silicon layer and the substrate.

According to some embodiments, the nitride buffer layer comprises a silicon oxy-nitride layer or a silicon nitride layer.

According to some embodiments, the protective condition layer further comprises an oxide buffer layer between the amorphous silicon layer and the substrate.

According to some embodiments, the oxide buffer layer comprises an in-situ steam growth (ISSG) oxide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are schematic diagrams illustrating a method of forming a semiconductor structure according to an embodiment of the present invention.

FIG. 5 is a schematic diagram illustrating a method of forming a semiconductor structure according to another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

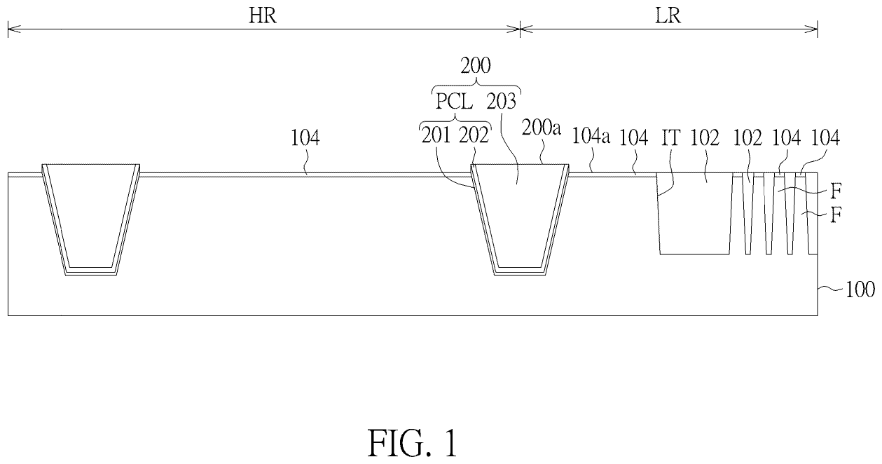

Please refer to FIGS. 1-4, which are schematic diagrams illustrating a method of forming a semiconductor structure according to an embodiment of the present invention. As shown in FIG. 1, first, a substrate 100 is provided, such as a silicon substrate, but not limited thereto. According to an embodiment of the present invention, the substrate 100 has a low-voltage device region LR and a high-voltage device region HR. According to an embodiment of the present invention, multiple fin structures F are formed within the low-voltage device region LR. According to an embodiment of the present invention, an insulating trench IT around the fin structure F is filled with an insulating layer 102 at this point. According to an embodiment of the present invention, for example, the insulating layer 102 can be a silicon oxide layer formed by a flowable chemical vapor deposition (FCVD) system. According to an embodiment of the present invention, for example, the insulating layer 102 has been annealed.

According to an embodiment of the present invention, after forming the trench isolation structure in the low-voltage device region LR, a trench isolation structure 200 is formed in the substrate 100 between the low-voltage device region LR and the high-voltage device region HR, and then the pad nitride layer (not shown) on the pad oxide layer 104 is removed. At this point, the top surface of the fin structure F and the top surface of the substrate 100 are still covered by the pad oxide layer 104. According to an embodiment of the present invention, the top surface 200a of the trench isolation structure 200 can be slightly higher than the top surface 104a of the pad oxide layer 104. Subsequently, a lithography process and an ion implantation process can be performed to form a high-voltage ion well HVW in the substrate 100 within the high-voltage device region HR.

According to an embodiment of the present invention, the trench isolation structure 200 includes, for example, a protective condition layer (PCL) and a trench-fill layer 203, wherein the protective condition layer PCL can be a multilayer film structure, interposed between the trench-fill layer 203 and the substrate 100. According to an embodiment of the present invention, the protective condition layer PCL includes, for example, an amorphous silicon layer 201. According to an embodiment of the present invention, the thickness of the amorphous silicon layer 201 is, for example, 50-100 angstroms. According to an embodiment of the present invention, the trench-fill layer 203 includes, for example, a silicon oxide layer (also known as a high-density plasma silicon oxide layer or HDP oxide layer) deposited by a high-density plasma chemical vapor deposition (HDPCVD) process.

According to an embodiment of the present invention, the protective condition layer PCL may further include a SiₓO_{y} layer 202, wherein x:y is between 1:1 and 1:2, disposed between the amorphous silicon layer 201 and the trench-fill layer 203. According to an embodiment of the present invention, the SiₓO_{y} layer 202 has a graded silicon content, with a higher silicon concentration near the amorphous silicon layer 201 and a lower silicon concentration near the trench-fill layer 203. According to an embodiment of the present invention, the thickness of the SiₓO_{y} layer 202 is, for example, 100-200 angstroms. According to an embodiment of the present invention, the amorphous silicon layer 201, the SiₓO_{y} layer 202, and the trench-fill layer 203 can be formed in-situ by an HDPCVD process. According to an embodiment of the present invention, the amorphous silicon layer 201, the SiₓO_{y} layer 202, and the trench-fill layer 203 do not need to be annealed. Therefore, the use of the protective condition layer PCL in the present invention can improve the problems of through-fin loading, the reduction of the critical dimension (Iso-Fin CD shrinkage) of isolated fins, and device shifting due to stress-induced cracking.

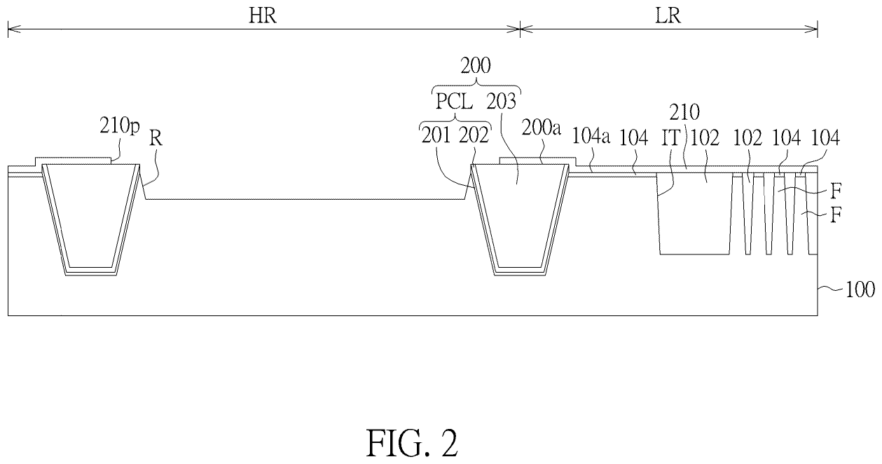

As shown in FIG. 2, a chemical vapor deposition (CVD) process is then performed to deposit a mask layer 210, such as a silicon nitride layer, on the entire substrate 100. A lithography process and an etching process are then performed to form an opening 210p in the mask layer 210, exposing the substrate 100 within the high-voltage device region HR. An etching process is then performed to etch downward through the opening 210p in the mask layer 210 into the substrate 100, forming a recessed region R.

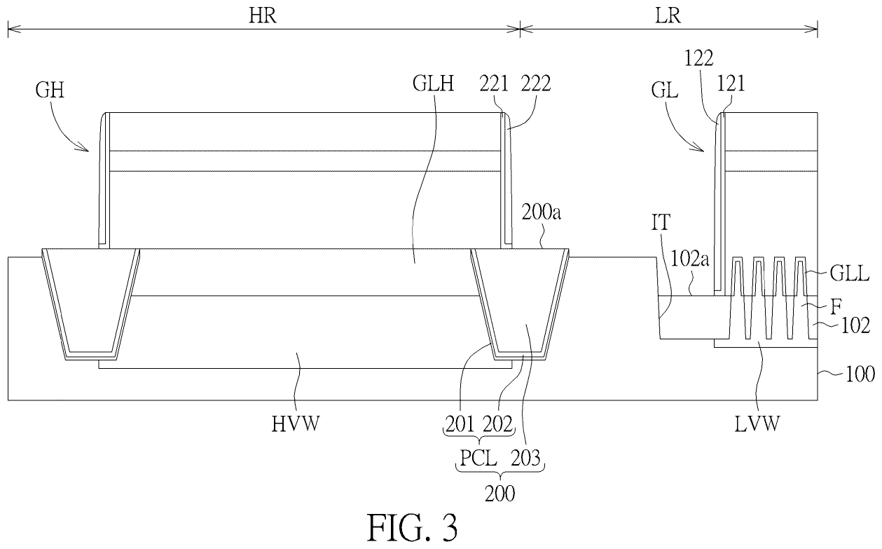

As shown in FIG. 3, an oxidation process is then performed to form a high-voltage gate oxide layer GLH within the recessed region R. Subsequently, the mask layer 210 is removed. Subsequently, an ion implantation process and a rapid thermal annealing process are performed to form a low-voltage ion well LVW in the low-voltage device region LR. A lithography process and an etch process are then performed to etch away a portion of the insulating layer 102 in the low-voltage device region LR to a predetermined depth. At this point, the upper portions of the fin structures F protrude from the top surface 102a of the insulating layer 102. An oxidation process, including but not limited to, an in-situ steam growth (ISSG) process, is then performed to form a low-voltage gate oxide layer GLL on the fin structures F protruding from the top surface 102 of the insulating layer 102. A deposition process, a lithography process, and an etch process are then performed to form dummy polysilicon gate structures GL and GH in the low-voltage device region LR and the high-voltage device region HR, respectively. Low-k sidewall spacers 221 and 121 are then formed on the dummy polysilicon gate structures GH and GL, respectively. Subsequently, an ion implantation process can be performed to form an N-type or P-type doped region in the substrate 100, such as a drain region or a source region of a transistor. An epitaxial growth process is then performed in the low-voltage device region LR to form an epitaxial structure on both sides of the dummy polysilicon gate structure GL. Sidewall spacers 222 and 122 are then formed on the low-k sidewall spacers 221 and 121, respectively.

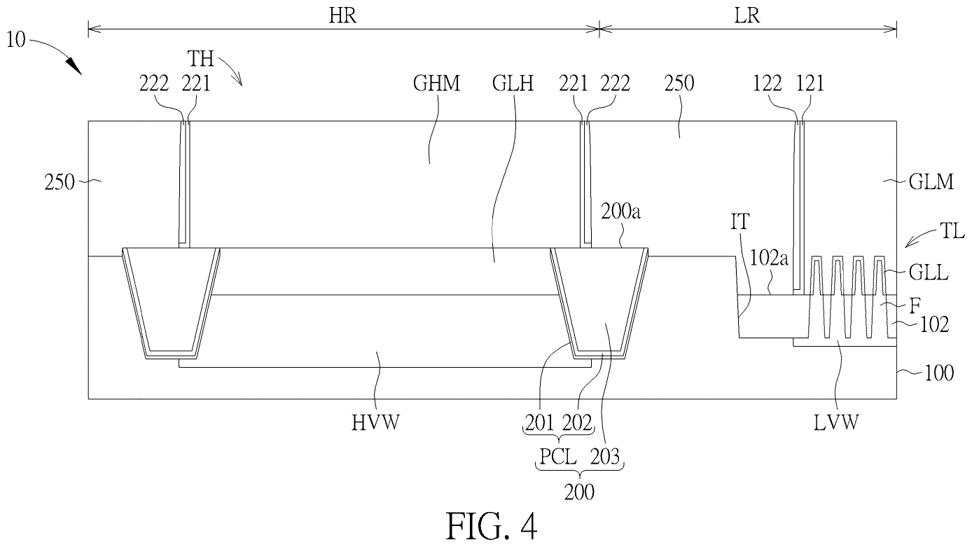

Subsequently, as shown in FIG. 4, a dielectric layer 250 is deposited on the entire substrate 100, followed by a replacement metal gate (RMG) process. The dummy polysilicon gate structures GH and GL are replaced with metal gates GHM and GLM, respectively, thereby forming a plurality of fin field effect transistors TL in the low-voltage device region LR and at least one high-voltage transistor TH in the high-voltage device region HR, thus completing the semiconductor structure 10. Since the RMG process is a well-known technology, its details will not be described further.

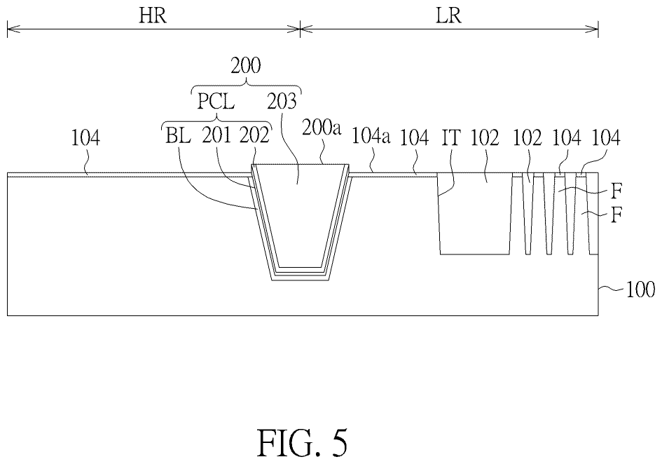

According to another embodiment of the present invention, as illustrated in FIG. 5, the protective condition layer PCL further includes a buffer layer BL located between the amorphous silicon layer 201 and the substrate 100. For example, the buffer layer BL may be a nitride buffer layer, including a silicon oxynitride layer or a silicon nitride layer, but is not limited thereto. For example, the buffer layer BL can be an oxide buffer layer, including an in-situ steam grown (ISSG) oxide layer, but is not limited thereto.

As shown in FIG. 4, the present invention provides a semiconductor structure 10 including: a substrate 100 having a low-voltage device region LR and a high-voltage device region HR; a plurality of fin field-effect transistors TL disposed in the low-voltage device region LR; at least one high-voltage transistor TH disposed in the high-voltage device region HR; and a trench isolation structure 200 disposed in the substrate 100 between the low-voltage device region LR and the high-voltage device region HR. The trench isolation structure 200 includes a trench-fill layer 203 and a protection condition layer PCL located between the trench-fill layer 203 and the substrate 100. According to an embodiment of the present invention, the protection condition layer PCL includes an amorphous silicon layer 201. According to an embodiment of the present invention, the thickness of the amorphous silicon layer 201 is 50-100 angstroms. According to an embodiment of the present invention, the trench-fill layer 203 includes a high density plasma silicon oxide (HDP oxide) layer.

According to an embodiment of the present invention, the protection condition layer PCL further includes a SiₓO_{y} layer 202, wherein x:y is between 1:1 and 1:2, disposed between the amorphous silicon layer 201 and the trench-fill layer 203. According to an embodiment of the present invention, the SiₓO_{y} layer 202 has a graded silicon content, with a higher silicon concentration near the amorphous silicon layer 201 and a lower silicon concentration near the trench-fill layer 203. According to an embodiment of the present invention, the thickness of the SiₓO_{y} layer 202 is 100-200 angstroms.

According to another embodiment of the present invention, as shown in FIG. 5, the protection condition layer PCL may further include a buffer layer BL located between the amorphous silicon layer 201 and the substrate 100. For example, the buffer layer BL may be a nitride buffer layer, including a silicon oxynitride layer or a silicon nitride layer, but is not limited thereto. For example, the buffer layer BL may be an oxide buffer layer, including an in-situ steam grown (ISSG) oxide layer, but is not limited thereto.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate having a low-voltage device region and a high-voltage device region thereon;
a plurality of finFETs disposed in the low-voltage device region;
at least one high-voltage transistor disposed in the high-voltage device region; and
a trench isolation structure disposed in the substrate between the low-voltage device region and the high-voltage device region, wherein the trench isolation structure comprises a trench-fill layer and a protective condition layer between the trench-fill layer and the substrate, and wherein the protective condition layer comprises an amorphous silicon layer.

2. The semiconductor structure according to claim 1, wherein the trench-fill layer comprises a high-density plasma (HDP) silicon oxide layer.

3. The semiconductor structure according to claim 1, wherein the amorphous silicon layer has a thickness of 50-100 angstroms.

4. The semiconductor structure according to claim 1, wherein the protective condition layer further comprises:
a SiₓO_{y} layer disposed between the amorphous silicon layer and the trench-fill layer, where x:y is between 1:1 and 1:2.

5. The semiconductor structure according to claim 4, wherein the SiₓO_{y} layer exhibits a graded silicon content, with a higher silicon concentration near the amorphous silicon layer and a lower silicon concentration near the trench-fill layer.

6. The semiconductor structure according to claim 4, wherein the SiₓO_{y} layer has a thickness of 100-200 angstroms.

7. The semiconductor structure according to claim 1, wherein the protective condition layer further comprises a nitride buffer layer between the amorphous silicon layer and the substrate.

8. The semiconductor structure according to claim 7, wherein the nitride buffer layer comprises a silicon oxy-nitride layer or a silicon nitride layer.

9. The semiconductor structure according to claim 1, wherein the protective condition layer further comprises an oxide buffer layer between the amorphous silicon layer and the substrate.

10. The semiconductor structure according to claim 9, wherein the oxide buffer layer comprises an in-situ steam growth (ISSG) oxide layer.

11. A method for forming a semiconductor structure, comprising:
providing a substrate having a low-voltage device region and a high-voltage device region thereon;
forming a plurality of finFETs in the low-voltage device region;
forming at least one high-voltage transistor in the high-voltage device region; and
forming a trench isolation structure in the substrate between the low-voltage device region and the high-voltage device region, wherein the trench isolation structure comprises a trench-fill layer and a protective condition layer between the trench-fill layer and the substrate, and wherein the protective condition layer comprises an amorphous silicon layer.

12. The method according to claim 11, wherein the trench-fill layer comprises a high-density plasma (HDP) silicon oxide layer.

13. The method according to claim 11, wherein the amorphous silicon layer has a thickness of 50-100 angstroms.

14. The method according to claim 11, wherein the protective condition layer further comprises:
a SiₓO_{y} layer disposed between the amorphous silicon layer and the trench-fill layer, where x:y is between 1:1 and 1:2.

15. The method according to claim 14, wherein the SiₓO_{y} layer exhibits a graded silicon content, with a higher silicon concentration near the amorphous silicon layer and a lower silicon concentration near the trench-fill layer.

16. The method according to claim 14, wherein the SiₓO_{y} layer has a thickness of 100-200 angstroms.

17. The method according to claim 11, wherein the protective condition layer further comprises a nitride buffer layer between the amorphous silicon layer and the substrate.

18. The method according to claim 17, wherein the nitride buffer layer comprises a silicon oxy-nitride layer or a silicon nitride layer.

19. The method according to claim 11, wherein the protective condition layer further comprises an oxide buffer layer between the amorphous silicon layer and the substrate.

20. The method according to claim 19, wherein the oxide buffer layer comprises an in-situ steam growth (ISSG) oxide layer.
